(19) United States
(12) Patent Application Publication
(10) Pub. No.: US 2014/0157546 A1
(43) Pub. Date: Jun. 12, 2014

(54) CONNECTION MECHANISM

(71) Applicant: Acer Incorporated, New Taipei City (TW)

(72) Inventors: Hsin-Tsung HO, New Taipei City (TW); Ming-Yen WU, New Taipei City (TW); Chao-Di SHEN, New Taipei City (TW); Yan-Lin KUO, New Taipei City (TW)

(73) Assignee: Acer Incorporated, New Taipei City (TW)

(21) Appl. No.: 13/951,357

(22) Filed: Jul. 25, 2013

(30) Foreign Application Priority Data
Dec. 10, 2012 (TW) 101146350

(51) Int. Cl. H05K 5/02; E05D 7/00

(52) U.S. Cl. CPC H05K 5/0226; E05D 7/00
USPC 16/221

(57) ABSTRACT

A connection mechanism connecting the main body and display of an electronic device includes an arm, a first hinge connecting the main body with the arm, a second hinge connecting the arm with the display, and a magnetic element disposed on the arm for exerting a magnetic attraction force on the display. When the arm rotates in a first direction relative to the main body with an included angle between the main body and the display smaller than a critical angle, a first torque opposite to the first direction is provided by the first hinge. When the arm continues rotating relative to the main body with the included angle between the main body and the display exceeding or equaling the critical angle, a second torque opposite to the first direction is provided by the first hinge, wherein the second torque exceeds the first torque.

### CROSS REFERENCE TO RELATED APPLICATIONS

The present application is based on, and claims priority from, Taiwan Patent Application No. 101146350, filed on Dec. 10, 2012, the disclosure of which is hereby incorporated by reference herein in its entirety.

### BACKGROUND OF THE INVENTION

1. Field of the Invention

The invention relates to a connection mechanism for connecting the main body and display of an electronic device, wherein the connection mechanism includes a two-stage torque hinge and a magnetic element.

2. Description of the Related Art

Electronic devices with two hinges have become popular. Conventional displays of electronic devices can be rotated via two hinges in multiple directions, thus facilitating wide viewing angles for users. However, unexpected rotation of the display around a second hinge may occur when rotating the display relative to the main body of the electronic device.

### BRIEF SUMMARY OF THE INVENTION

The invention provides a connection mechanism with two hinges for connecting the main body and display of an electronic device. The connection mechanism has a two-stage torque hinge and a magnetic element, so as to prevent the unexpected rotation of the display around on the second hinge occurring when rotating the display relative to the main body of the electronic device.

An embodiment of the invention provides a connection mechanism for connecting the main body and display of an electronic device. The connection mechanism includes an arm, a first hinge connecting the main body with the arm, a second hinge connecting the arm with the display, and a magnetic element disposed on the arm for exerting a magnetic attraction force Fₘ, on the display. When the arm rotates in a first direction relative to the main body with an included angle between the main body and the display smaller than a critical angle, a first torque T₁ opposite to the first direction is provided by the first hinge. When the arm rotates in the first direction relative to the main body with the included angle between the main body and the display exceeding or equaling the critical angle, a second torque T₂ opposite to the first direction is provided by the first hinge, wherein the second torque exceeds the first torque (T₂>T₁).

Another embodiment of the invention provides a connection mechanism, wherein a third torque T₃ opposite to the first direction is provided by the second hinge, the distance between the first hinge and a top end of the display is indicated as S, the distance between the first and second hinges is indicated as S₁, the distance between the top end of the display and the second hinge is indicated as S₂, and the magnetic attraction force Fₘ is exerted on the display by the magnetic element. When a first force F₁ is applied to the top end of the display, the first torque T₁ is correspondingly provided by the first hinge (F₁=T₁/S), wherein the magnetic attraction force Fₘ satisfies the following inequality: Fₘ>(F₁×S₂−T₃)/S₁. When a second force F₂ is applied to the top end of the display, the second torque T₂ is correspondingly provided by the first hinge (F₂=T₂/S), wherein the magnetic attraction force Fₘ satisfies the following inequality: Fₘ<(F₂×S₂−T₃)/S₁.

### BRIEF DESCRIPTION OF THE DRAWINGS

The invention can be more fully understood by reading the subsequent detailed description and examples with references made to the accompanying drawings, wherein:

FIGS. 1A and 1B are schematic diagrams of an electronic device according to an embodiment of the invention;

FIG. 2 is a schematic diagram showing how the display rotates along the second hinge;

FIG. 3 is a schematic diagram showing how the display and the arm rotate counterclockwise along the first hinge;

FIG. 4 is a schematic diagram showing the display facing upward for viewing by the user;

FIG. 5 is a schematic diagram of an electronic device according to another embodiment of the invention, wherein the second hinge exerts a spring force on the display with the bottom end thereof in contact with the arm;

FIG. 6 is a schematic diagram showing the relation of the magnetic attraction force and the two-stage torques according to an embodiment of the invention.

### DETAILED DESCRIPTION OF THE INVENTION

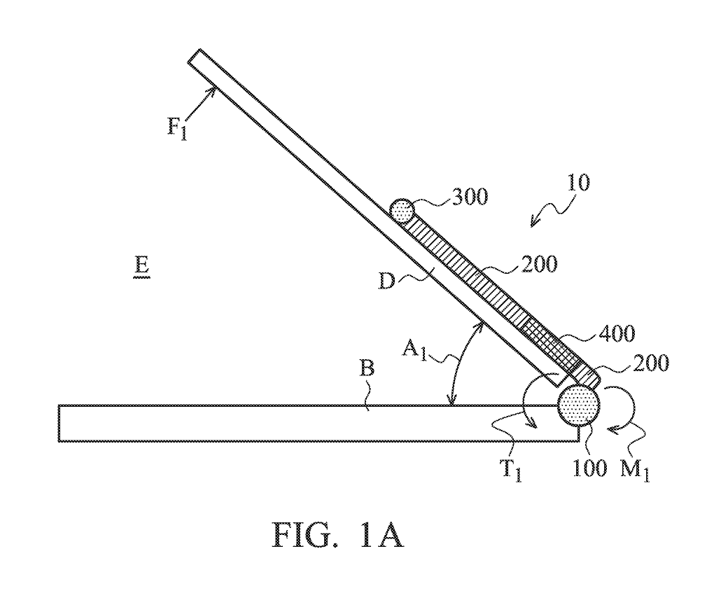

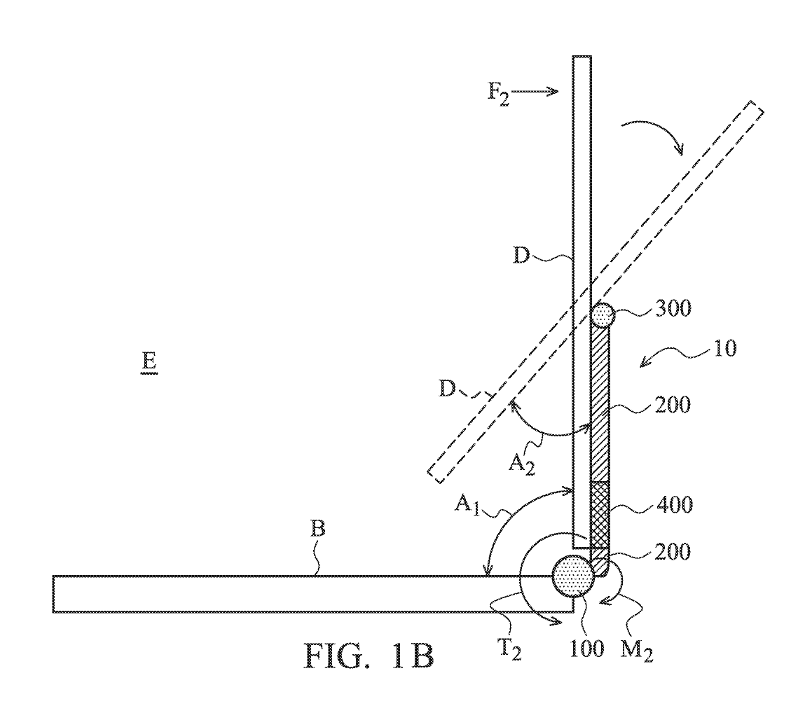

FIGS. 1A and 1B are schematic diagrams of an electronic device according to an embodiment of the invention. As shown in FIG. 1A, the electronic device E includes a connection mechanism 10, a main body B, and a display D. The connection mechanism 10 includes a first hinge 100, an arm 200, a second hinge 300, and a magnetic element 400, wherein the first hinge 100 and the second hinge 300 are disposed at two ends of the arm 200. The first hinge 100 pivotally connects the main body B with the arm 200, and the second hinge 300 pivotally connects the display D with the arm 200. The magnetic element 400 is disposed on the arm 200, adjacent to the first hinge 100, and exerts a magnetic attraction force on the display D to prevent the display D from separating from the arm 200 when opening from the main body B.

In this embodiment, the first hinge 100 provides two different torques when rotating the display D. As the arm 200 rotates clockwise (first direction) relative to the main body B with an included angle A₁ between the main body B and the display D smaller than a critical angle, a first torque T₁ in a counterclockwise direction is provided by the first hinge 100 (FIG. 1A). When the arm 200 continues rotating clockwise (first direction) relative to the main body B with the included angle A₁ between the main body B and the display D exceeding or equaling the critical angle, a second torque T₂ in a counterclockwise direction is provided by the first hinge 100 (FIG. 1B), wherein T₂>T₁. The critical angle in this embodiment is about 90 degrees.

When the included angle A₁ between the main body B and the display D is smaller than 90 degrees (FIG. 1A) with a first force F₁ applied to the display D to exert a first moment M₁ on the first hinge 100, a torque element in the first hinge 100 correspondingly provides the first torque T₁ against the first moment M₁. As the first moment M₁ exceeds or equals the first torque T₁, the display D can be rotated clockwise relative to the first hinge 100. Similarly, when the included angle A₁ between the main body B and the display D exceeds or equals 90 degrees (FIG. 1B) with a second force F₂ applied to the display D to exert a second moment M₂ on the first hinge 100, the torque unit in the first hinge 100 correspondingly provides a second torque T₂ against the second moment M₂. As the second moment M₂ exceeds or equals the second torque T₂, the display D can be further rotated clockwise relative to the first hinge 100. In this embodiment, the first torque T₁ is between 5.4 N-m and 5.6 N-m, and the second torque T₂ is between 6.4 N-m and 6.6 N-m.

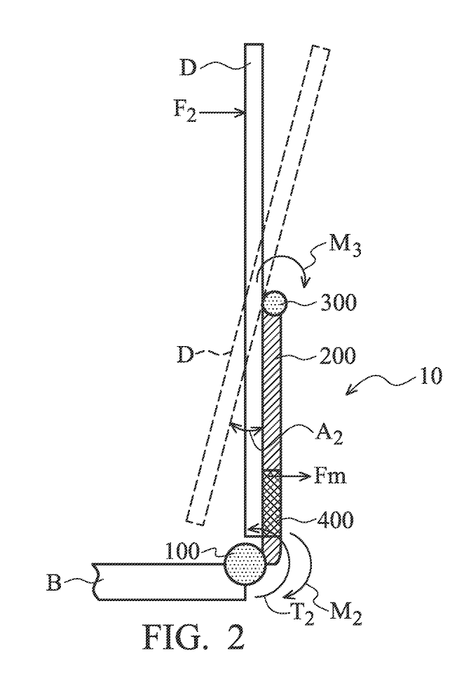

Note that, under conditions in which the included angle A₁ between the main body B and the display D is smaller than 90 degrees, if the moment exerted on the second hinge 300 provided by the first force F₁ is smaller than that exerted on the second hinge 300 provided by the magnetic element 400, the display D cannot be separated from the arm 200 to rotate around the second hinge 300. Conversely, under conditions in which the included angle A₁ between the main body B and the display D exceeds or equals 90 degrees (FIGS. 1B and 2), since the second torque T₂ provided by the first hinge 100 exceeds the first torque T₁, the second moment M₂ (or second force F₂) has to be increased to overcome the second torque T₂ so that the display D can rotate around the first hinge 100. Meanwhile, if a third moment M₃ exerted on the second hinge 300 by the second force F₂ exceeds the reverse moment exerted on the second hinge 300 by the magnetic attraction force Fₘ provided by the magnetic element 400, the display D can be rotated around the second hinge 300.

By applying the two-stage torque hinge (first hinge 100) and the arm 200 with the magnetic element 400, the display D can be rotated relative to the second hinge 300 only when the included angle A₁ between the main body B and the display D exceeds or equals the critical angle. Thus, the unexpected rotation of the display D around the second hinge 300 that occurs when opening the display from the main body of the electronic device can be prevented.

The display D (FIG. 1B) can be rotated around the second hinge 300 to form a rotation angle A₂ between the display D and the arm 200, wherein the rotation angle A₂ is from 0 to 180 degrees. The critical angle of the aforementioned embodiment is about 90 degrees, however, the critical angle may also be designed in different angles (such as 90 degrees to 110 degrees).

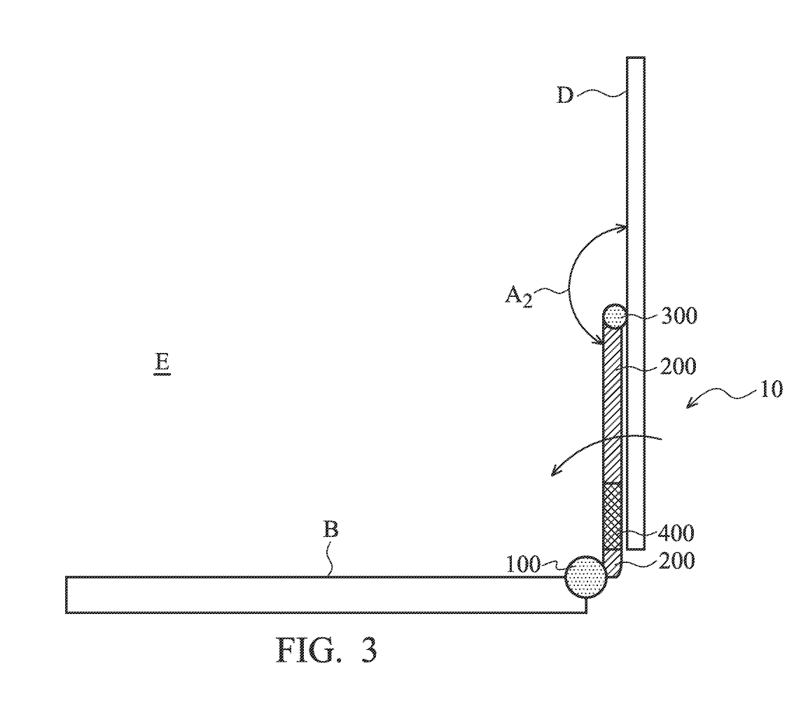

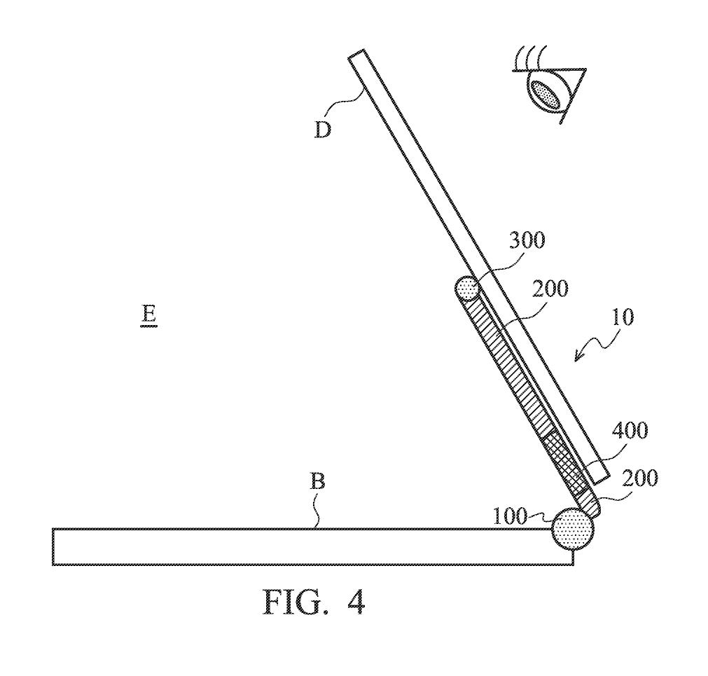

In some embodiments, a stopper (not shown) may be further disposed in the first hinge 100. When the included angle A₁ between the main body B and the display D exceeds or equals the critical angle, the stopper can stop the arm 200 from rotating clockwise around the first hinge 100 relative to the main body B, and the display D may be further rotated around the second hinge 300 until the rotation angle A₂ between the display D and the arm 200 reaches 180 degrees. In this state, the display D and the arm 200 can be rotated counterclockwise around the first hinge 100 (as indicated by the arrow in FIG. 3). Thus, the display D can face upward to provide users with different viewing angles, wherein the eye shown in FIG. 4 represents the viewing direction of a user.

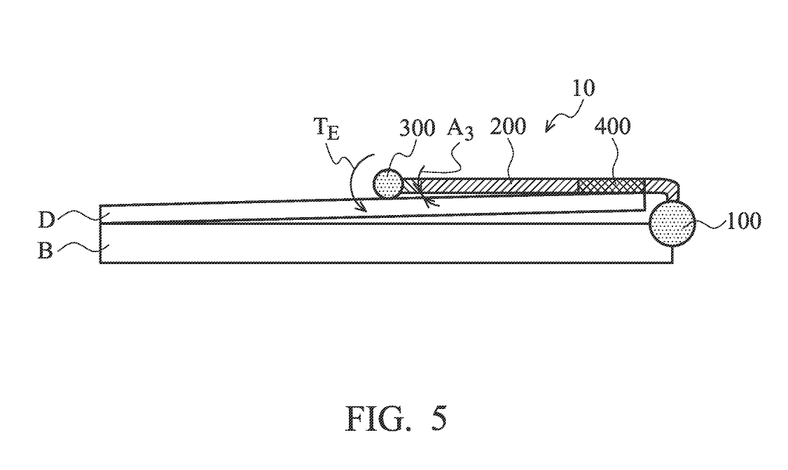

Referring to FIG. 5, in another embodiment of the invention, the second hinge 300 further includes a spring element (not shown), such as a torsion spring, exerting a spring force T_{E} on the display D with the bottom end thereof in contact with the arm 200, wherein an inclined angle A₃ is formed between the display D and the arm 200.

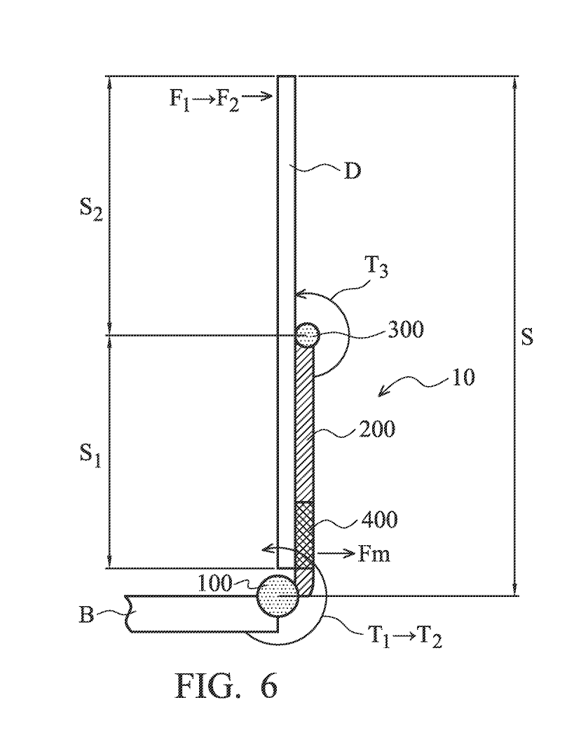

Specifically, the magnetic attraction force Fₘ provided by the magnetic element 400, the torques T₁ and T₂ and each distance parameters are shown in FIG. 6. The detailed relationships between the forces and the distances are described below. The distance between the first hinge 100 and a top end of the display D is indicated as S, the distance between the first and second hinges 100 and 300 is indicated as S₁, the distance between the top end of the display D and the second hinge 300 is indicated as S₂, and Fₘ represents the magnetic attraction force exerted on the display D by the magnetic element 400. When the first force F1 is applied to the top end of the display D, the first torque T₁ (F₁=T₁/S) is correspondingly provided by the first hinge 100, and a third torque T₃ opposite to the first direction is provided by the second hinge 300, wherein the magnetic attraction force Fₘ, satisfies the following inequality:

Fₘ>(F₁×S₂−T₃)/S₁

When the second force F₂ is applied on the top end of the display D, the second torque T₂ (T₂>T₁, and F₂=T₂/S) is correspondingly provided by the first hinge 100, wherein the magnetic attraction force Fₘ satisfies the following inequality:

Fₘ<(F₂×S₂−T₃)/S₁

As described above, the invention provides a connection mechanism with two hinges. According to the aforementioned mechanisms, unexpected rotation of the display around the second hinge can be prevented to facilitate convenient usage of the electronic device.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A connection mechanism for connecting a main body and a display of an electronic device, comprising:
an arm;
a first hinge, connecting the main body with the arm;
a second hinge, connecting the arm with the display; and
a magnetic element, disposed on the arm for exerting a magnetic attraction force Fₘ on the display, wherein
when the arm rotates in a first direction relative to the main body with an included angle between the main body and the display smaller than a critical angle, a first torque T₁ opposite to the first direction is provided by the first hinge, and when the arm rotates in the first direction relative to the main body with the included angle between the main body and the display exceeding or equaling the critical angle, a second torque T₂ opposite to the first direction is provided by the first hinge, wherein the second torque exceeds the first torque (T₂>T₁).

2. The connection mechanism as claimed in claim 1, wherein the critical angle is from 90 to 110 degrees.

3. The connection mechanism as claimed in claim 1, wherein the magnetic element is adjacent to the first hinge.

4. The connection mechanism as claimed in claim 1, wherein the first hinge has a stopper stopping the arm from rotating relative to the main body while the included angle between the main body and the display exceeds or equals the critical angle.

5. The connection mechanism as claimed in claim 1, wherein a rotation angle between the display and the arm is from 0 to 180 degrees.

6. The connection mechanism as claimed in claim 1, wherein the first torque is between 5.4 N-m and 5.6 N-m.

7. The connection mechanism as claimed in claim 1, wherein the second torque is between 6.4 N-m and 6.6 N-m.

8. The connection mechanism as claimed in claim 1, wherein the second hinge exerts a spring force on the display with the bottom end thereof in contact with the arm, and an inclined angle is formed between the display and the arm.

9. The connection mechanism as claimed in claim 5, wherein when the rotation angle is 180 degrees, the display and the arm rotate along the first hinge in a second direction opposite to the first direction.

10. The connection mechanism as claimed in claim 1, wherein a third torque T₃ opposite to the first direction is provided by the second hinge, the distance between the first hinge and the top end of the display is indicated as S, the distance between the first and second hinges is indicated as S₁, the distance between the top end of the display and the second hinge is indicated as S₂, and the magnetic attraction force Fm is exerted on the display by the magnetic element, wherein
when a first force F₁ is applied to the top end of the display, the first torque T₁ is correspondingly provided by the first hinge, and F₁=T₁/S, wherein the magnetic attraction force Fₘ satisfies the following inequality:
Fₘ>(F₁×S₂−T₃)/S₁;
wherein when a second force F₂ is applied to the top end of the display, the second torque T₂ is correspondingly provided by the first hinge, and F₂=T₂/S, wherein the magnetic attraction force Fₘ satisfies the following inequality:
Fₘ<(F₂×S₂−T₃)/S₁.
